(19) United States
(12) Patent Application Publication
(10) Pub. No.: US 2025/0274200 A1
(43) Pub. Date: Aug. 28, 2025

(54) Device and Method for Radio Transmission of Local Measurements of Physical Values, Particularly by Way of Quasi-Gaussian PPM Pulses

(71) Applicant: STE INDUSTRIES S.R.L., Milano (IT)

(72) Inventors: Paolo Maria Moiraghi, Frazione Divisa (IT); Guido Moiraghi, Milano (IT)

(21) Appl. No.: 18/862,377

(22) PCT Filed: May 2, 2023
(86) PCT No.: PCT/IB2023/054556

§ 371 Date: Nov. 1, 2024

(30) Foreign Application Priority Data
May 4, 2022 (IT) 102022000009020

(51) Int. Cl. H04B 17/12; H03K 7/04; H04L 25/49

(52) U.S. Cl. CPC H04B 17/12; H03K 7/04; H04L 25/4902

(57) ABSTRACT

A device for the radio transmission of local measurements of physical values includes a microcontroller, a pulse generator connected thereto to generate at least one PPM signal, and an antenna for radio transmission of the PPM signal. The pulse generator includes an oscillator and a power amplifier with an input connected to the oscillator to emit the PPM signal on the basis of a selective activation of the oscillator and of the power amplifier by respective driving signals with rectangular pulses generated by the microcontroller. These driving signals include, for each PPM pulse to be generated, a respective rectangular pulse, so that the oscillator is activated prior to, and deactivated after, the respective instants of activation and deactivation of the power amplifier. The rectangular pulse supplied to the power amplifier is low-pass filtered to slow the deactivation of the amplifier while the oscillator remains active by the respective rectangular pulse.

The present invention relates to a device and a method for the radio transmission of local measurements of physical values, particularly for the radio transmission of such measurements by way of quasi-Gaussian PPM pulses. The values of the locally performed measurements that are transmitted may be values of pressure, temperature, humidity, deformation, vibration, or the like, collected by means of suitable sensors on structures which, for example, rotate, oscillate or vibrate. A particular but not exclusive use of the invention is vehicle telemetry, for example, the use of the device on tires in order to transmit by radio their internal pressure (Tire Pressure Monitoring System—TPMS) or other physical values or parameters measured on the tire or on the wheel that contains it. However, the present invention is not limited to the field of vehicles or tires and it is suitable to be used in any context in which a locally performed measurement of some physical value or parameter needs to be transmitted by radio with low power consumption or short range.

Devices for transmitting measurements of physical values such as temperature, pressure, humidity, deformation, etc., capable of converting such measurements into data strings that are then transmitted via radio, are known in the background art.

In order to significantly reduce the power consumption of these transmission devices, a transmitter device is known from U.S. Pat. No. 10,284,120 which comprises a microcontroller configured to receive a signal related to at least one measured value and to control a pulse generator so that it generates a corresponding Pulse Position Modulation or PPM signal, which is then transmitted via radio. The pulse generator of this known solution comprises an oscillator and a power amplifier to amplify the pulses in output from the oscillator and to emit the PPM signal. The microcontroller is configured, for each pulse of the PPM signal to be generated, to activate only the oscillator for a first time period and then to also activate the amplifier only for a second time period that follows the first time period, deactivating both at the same time at the end of the second time period.

One drawback of the solution known from U.S. Pat. No. 10,284,120 is that the pulses generated in the above-described manner, lasting a few microseconds, may not comply with the regulations of certain countries in terms of spurious emissions, for example provided in the ETSI EN 300 220-1 and/or CFR 47 FCC part 15.231 standards.

To overcome this problem, it would be possible to use a microcontroller that, by means of digital filters, is adapted to shape the pulses to be transmitted so as to have a desired frequency behavior, i.e., with any out-of-band peaks below a certain threshold in dBm. To perform these operations, however, the microcontroller should have hardware with adequate computing power, in particular having speeds of at least 100 MHz, as in the DSPs of the microcontrollers currently used in the mobile telephone sector. However, this solution would increase power consumption and in any case would entail an increase in complexity.

The aim of the present invention is to provide a device and method for the radio transmission of PPM pulses that is capable of improving the background art in one or more of the above aspects.

Within the scope of this aim, an object of the invention is to generate PPM pulses with a duration of a few microseconds in one of the (free) bands allowed for short-range devices (SRDs), for example, one of the ISM bands or, more generally, SRD bands, such as those around 434 MHz, 315 MHz, 868 MHz, 915 MHz, 2.4 GHz or 4.8 GHz, so as to reduce spurious emissions compared to the background art while maintaining the advantages of the ultra-low power consumption of the above-mentioned background art.

Another object of the invention is to devise an RF transmission device that is adapted to be used in a physical device in an IoT (Internet of Things) network, and in particular has a small form factor, ultra-low power consumption, and low production costs.

A further object of the invention is to avoid, for the purpose of PPM pulse generation, microcontrollers with high clock speeds, in particular higher than 3-16 MHz.

Not least object of the invention is to overcome the drawbacks of the background art in a manner that is alternative to any existing solutions.

This aim, as well as these and other objects that will become better apparent hereinafter, are achieved by a device according to claim 1, optionally provided with one or more of the characteristics of the dependent claims.

The aim and objects of the invention are also achieved by a method according to claim 9, optionally provided with one or more of the characteristics of the dependent claims.

Further characteristics and advantages of the invention will become better apparent from the description of preferred but not exclusive embodiments of the device and method according to the invention, illustrated by way of non-limiting example in the accompanying drawings, wherein:

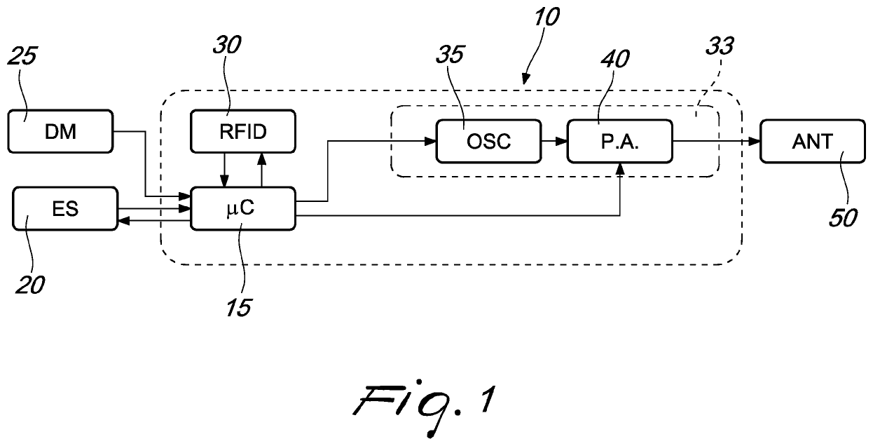

FIG. 1 is a block diagram of a transmission device according to the invention;

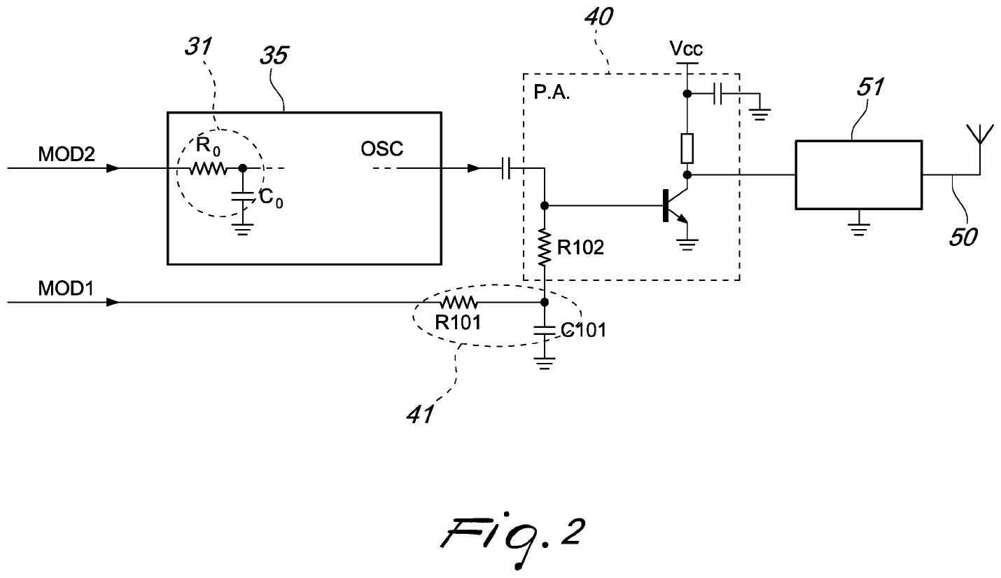

FIG. 2 is a more detailed block diagram of the pulse generation means of the device of the preceding figure;

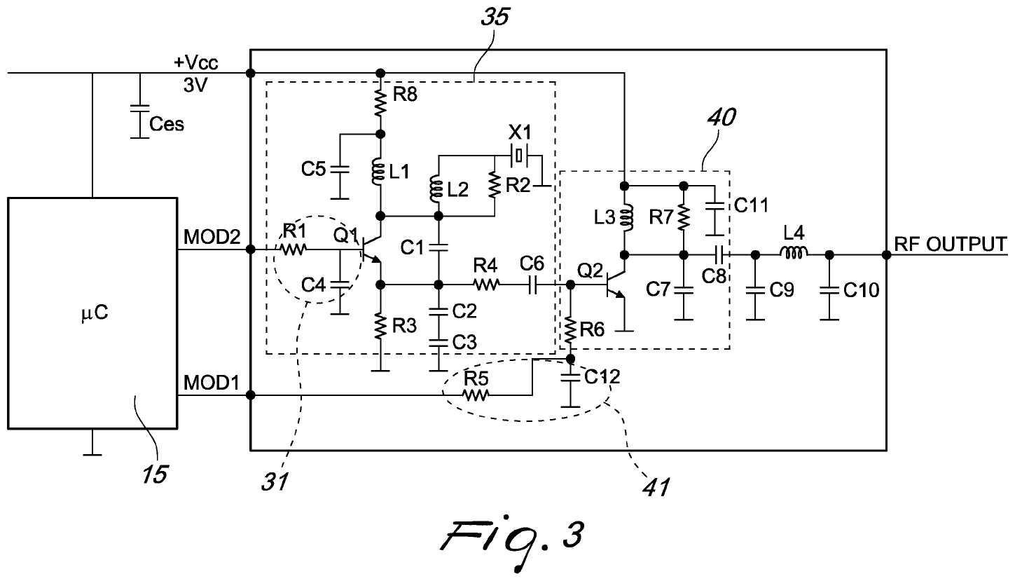

FIG. 3 is a view of the detailed circuit of the pulse generation means of FIG. 1;

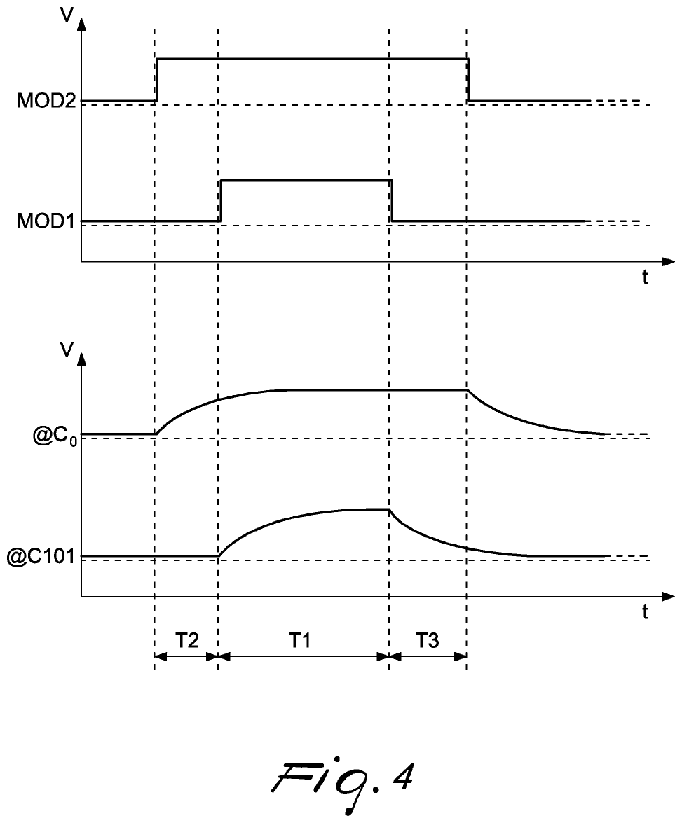

FIG. 4 plots the behavior over time of the MOD1 and MOD2 driving signals and the corresponding voltage generated on the capacitors at the inputs of the respective transistors of FIG. 3;

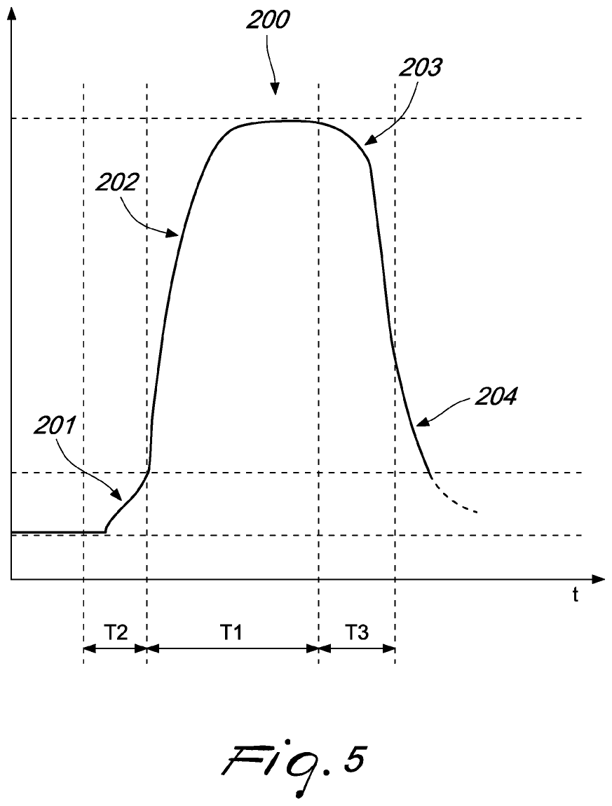

FIG. 5 plots the RF pulse at the output of the pulse generation means of FIG. 3;

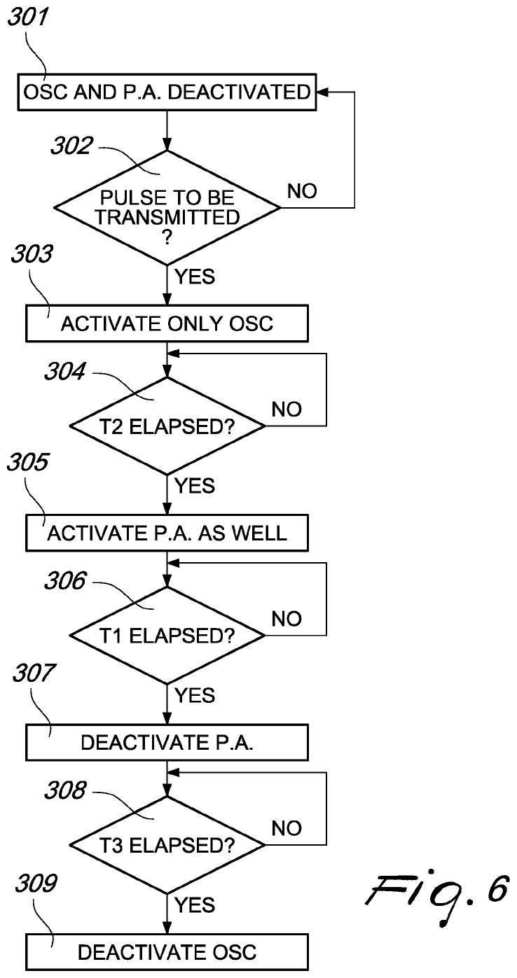

FIG. 6 is a flowchart of a method according to the invention;

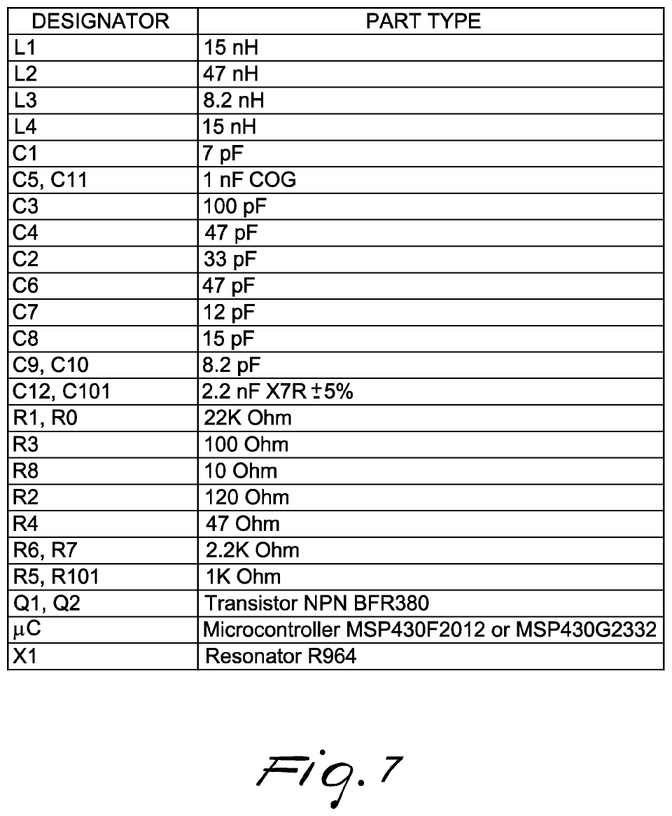

FIG. 7 is a legend with example values of the components of the circuit of FIG. 3;

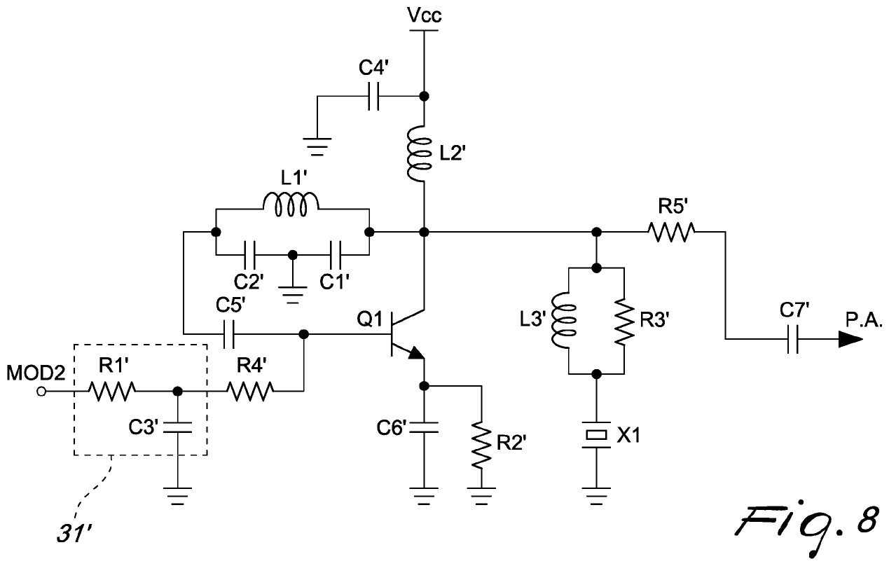

FIG. 8 is a view of an oscillator that can be used in a second embodiment as an alternative to the oscillator used in FIG. 3;

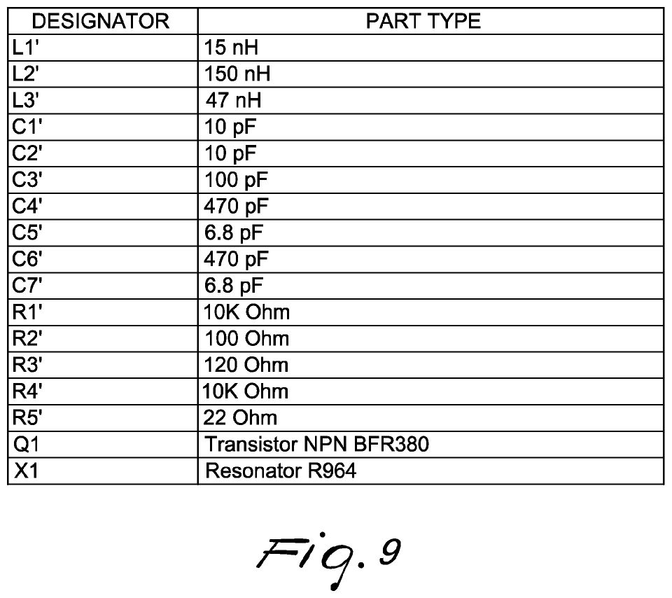

FIG. 9 is a legend with example values of the components of the oscillator of FIG. 8.

With reference to the cited figures, a device for the radio transmission of PPM signals according to the invention, particularly for telemetry applications, is generally designated by the reference numeral 10 and comprises a microcontroller 15 and pulse generation means 33 connected to the microcontroller 15 so as to be driven by the latter. The transmission device 10 is advantageously a short-range device powered by a power source 20, for example, a battery or an energy-harvesting source.

The microcontroller 15 is adapted to receive in input one or more detection signals representative of one or more measurement values of one or more physical values. The microcontroller 15 is, moreover, adapted to drive the pulse generation means 33 so that they generate Pulse Position Modulation (PPM) signals comprising, in encoded form, information corresponding to the measurement values received by the microcontroller 15 by way of the detection signals.

The detection signals originate from detection means 25 that are connected or connectable to the microcontroller 15 and are adapted to detect one or more measurements of a certain physical value (for example, one or more among pressure, temperature, acceleration, vibration, voltage, etc.) and to generate detection signals that correspond to the values of such measurements. The detection means 25 can substantially consist of at least one transducer (“DM” in the figures) for each physical value to be measured. The transducer DM can be connected to an appropriate input of the microcontroller 15 and can be a sensor selected from the group comprising, for example, a pressure sensor, a temperature sensor, a vibration sensor, an accelerometer, a magnetometer, a strain gauge, an inductive sensor, a voltage or current detector, etc.

The detection means 25, as well as an optional RFID tag 30 of the transmission device 10, may optionally be powered by the same microcontroller 15.

The pulse generation means 33 are connected in output, via an optional impedance matching stage 51, to at least one antenna 50, in order to transmit by radio the PPM signals generated by the generation means 33, so that the PPM signals are received via radio by a remote receiver. The remote receiver, not shown, may be for example the one described in PCT Application No. WO 2012/150565 A2. The remote receiver may optionally be a short distance from the transmission device 10, for example, on board a same vehicle in which one or more transducers DM are mounted.

The PPM signals are pulsed signals (“PPM pulses”), are per se known and are the result of a PPM modulation of a radio frequency (“RF”) carrier. In the case of the present invention, the RF carrier is preferably selected in one of the free bands for short-range devices, for example ISM. In the embodiment shown, this frequency is substantially 434.35 MHz but, clearly, by appropriately assigning values to the electronic components of the circuits shown in detail herein, it is possible to have any carrier frequency among those available for short-range devices.

A PPM signal generated and transmitted by the transmission device according to the invention is formed by at least one frame comprising a plurality of pairs of PPM pulses that encode a value or a sequence of measurement values, for example a value of pressure, temperature, deformation, voltage, acceleration, speed, electric current, and/or the like. The first pulse of each pair (“trigger pulse”) is generated periodically over time, for example every S1 microseconds (where S1 is a fixed value preferably comprised between 200 and 500, e.g., 400). The second pulse of each pair (“data pulse”) is instead at a variable distance with respect to the first pulse based on the binary value to be encoded, in a window positioned n·S2 microseconds after the first pulse, where n·S2<S1 and “n” is an integer associated with a respective, predetermined binary value. The distance between the first and second pulses may be comprised between 30 and 120 microseconds, for example between 50 and 90 microseconds, while the duration of each pulse is fixed and may be a few microseconds, for example comprised between 1 and 5 microseconds.

The message transmitted with one frame can be of 64 bits, consisting of 34 PPM pulses and with a duration of less than 6 milliseconds, wherein one pair of PPM pulses can be used to identify the start of the frame and the remaining 16 pairs of PPM pulses contain the data item to be transmitted.

As an alternative, the PPM signal generated and transmitted by the transmission device according to the invention can be provided with single pulses instead of pulse pairs, wherein each pulse of the PPM signal is the trigger pulse of the data pulse that follows it.

PPM modulation is performed by the transmission device 10 on the detection signals received by the microcontroller 15. In particular, words that correspond to measurement values of at least one physical value, for example bit sequences that correspond to an encoding of the measurement values, are modulated (PPM). Downstream of the microcontroller, modulation is then performed at the carrier frequency RF for the purpose of subsequent radio transmission of the PPM signal, as in the present invention.

The microcontroller 15 can be a microcontroller with a low clock speed, for example on the order of 1 MHz, and programmed so as to generate in output driving signals of the generation means, better described below. The microcontroller 15, for example, may be one of those in the family known commercially as MSP430, by Texas Instruments, for example MSP430F2012 or MSP430G2332.

The pulse generation means 33 comprise an oscillator 35 the output of which is connected to the input of a power amplifier (“P.A.”) 40, so that the latter amplifies the radio-frequency signals (“RF signals”) emitted by the oscillator 35 and generates in output the PPM pulses that will be transmitted via radio. The gain of the power amplifier 40 can be comprised between 10 and 20.

The oscillator 35 may have an RC stage 31 or 31′ in input, schematically represented by the resistor R0 and the capacitor C0 in FIG. 2.

Both the oscillator 35 and the power amplifier 40 are driven by the microcontroller 15, which is programmed to generate, on its corresponding outputs, a first signal MOD1 for driving the power amplifier 40 and a second signal MOD2 for driving the oscillator 35. The signals MOD1 and MOD2 consist essentially of rectangular voltage or current pulses, i.e., signals that assume only a low (null) value and a high value, with both values preferably being temperature-independent, i.e., not varying significantly over the operating temperature range of the transmission device 10, which can be comprised between −25° C. and +85° C. or possibly between −40° C. and +125° C. Each PPM pulse to be transmitted corresponds to a single rectangular pulse of the first signal MOD1 and a single rectangular pulse of the second signal MOD2, applied as explained hereinafter.

In the embodiment shown in FIG. 2 and, in greater detail, in FIG. 3, the signals MOD1 and MOD2 are constituted by rectangular voltage pulses having a low value equal to zero volts and a high value that can be substantially equal to the DC supply voltage +Vcc of the transmission device 10 (for example, 3V or a value comprised between 2.4V and 3.6V). In the example shown, the voltage +Vcc can be generated using a CR lithium battery.

Advantageously, the microcontroller 15 is connected to the input of the power amplifier 40 with the interposition of an RC filter 41, schematically represented in FIG. 2 by the resistor R101 (connected to the output MOD1 of the microcontroller 15) and the capacitor C101 connected to the ground and connected to a base resistor R102 of a BJT transistor of the power amplifier 40. Through the RC filter 41, which is a low-pass filter, the rising and falling edge of the signal MOD1 (which would otherwise be stepped) applied to the input of the amplifier 40 is slowed down between the output MOD1 of the microcontroller 15 and the input of the power amplifier 40, with a time constant essentially defined by the resistor and capacitor of the low-pass filter 41, i.e., by the product of their respective resistance and capacitance values.

With reference to the embodiment shown in FIG. 3, which provides more detail about the general structure of the transmission device 10 than the preceding figures, the oscillator 35 of the pulse generation means 33 comprises a Colpitts oscillator in the “common base” configuration and coupled to a SAW (Surface Acoustic Wave) resonator X1, which allows said oscillator 35 to achieve a stable frequency value Fo (in the example shown, equal to 434.35 MHz). The oscillator 35 is of a per se known type, for example from U.S. Pat. No. 8,134,416 B2, incorporated herein by reference.

The oscillator 35 can comprise a single RF transistor Q1, which can be an npn-type BJT and, in the specific example shown, can have a cutoff frequency of 14 GHz at 40 mA. The on/off switching of the oscillator 35 is achieved respectively with the high/low level of the voltage signal MOD2 that arrives from the corresponding output MOD2 of the microcontroller 15 and is applied to the base of the transistor Q1 via a base resistor R1. Advantageously, the same base of transistor Q1 is connected to the ground by means of a capacitor C4, which essentially defines, together with the resistor R1, a time constant R1·C4 adapted to determine the start-up time (T2) of the oscillator 35, i.e., the rate at which the oscillation amplitude rises to a stable value.

The SAW resonator X1 is connected between the ground and the collector of the transistor Q1 of the oscillator 35, with the interposition in series of an inductive-resistive stage formed by the inductor L2 and the resistor R2.

The oscillation frequency Fo is substantially determined by an inductor L1 (connected between the collector of the transistor Q1 and the power supply +Vcc, possibly with the interposition of a low-resistance resistor R8), by the capacitor C1 (between the collector and emitter of Q1), and by the series of capacitors C2 and C3 connected to the ground. At the instant in which the Colpitts oscillator is activated by the rising edge of the second driving signal MOD2, the (SAW) resonator X1 is a pure capacitance and oscillation begins at a frequency that is slightly higher than the target frequency. As soon as the resonator X1 begins to oscillate (mechanically), the resonator X1 is equivalent to an LCR circuit with the effect of dragging the Colpitts oscillator to the target frequency. This frequency corresponds to the parallel resonance frequency of the resonator X1 and is approximately 150 KHz to 250 KHz higher than the nominal series resonance frequency of the resonator X1.

As an alternative to the specific embodiment of the oscillator 35 shown in the device of FIG. 3, it is possible to use a Hartley-type oscillator always coupled to a SAW resonator X1 and to an input RC stage 31′, such as the one of FIG. 8. In this case, the Hartley oscillator is preferably in a “common emitter” configuration, and the phase reversal that allows oscillation is performed by the inductor L1′, connected between the collector and the base of the bipolar transistor Q1 (which can be the same npn transistor as in FIG. 3 and FIG. 7), in parallel to the series of capacitors C1′ and C2′.

The oscillator of FIG. 8 is stabilized at the oscillation frequency through the SAW resonator X1, which is connected between the ground and the collector of the transistor Q1 with the series interposition of an inductive-resistive stage formed by the parallel between the inductor L3′ and the resistor R3′.

The oscillator of FIG. 8 preferably uses the inductor L1′ in parallel with the capacitive divider C1′-C2′ with tap connected to ground instead of a tapped inductor with single capacitor in parallel, as is usually the case. Moreover, the oscillator of FIG. 8 may also comprise a leveling inductor or choke L2′ (which has a high reactance at the oscillation frequency) and a capacitor C5′ to bring the radiofrequency signal to the base of the transistor Q1, blocking the DC component. Toward the DC supply Vcc and the ground, the transistor Q1 of the oscillator can comprise respective bypass capacitors C4′ and C6′ to block the radiofrequency noise and, in the case of the emitter capacitor C6′, increase the gain of the amplifier by virtue of the parallel with the resistor R2′.

The RC series group formed by the resistor R5′ and the capacitor C7′ transfers the signal from the output of the oscillator (tap on the collector of Q1) to the input of the power amplifier 40, adapting it to the corresponding input impedance.

The power amplifier 40 is preferably adapted to bring the peak power of the RF pulse of the oscillator 35 to +13 or +14 dBm (25 mW−conducted power on 50 Ω).

The power amplifier 40 advantageously comprises a single transistor Q2, which is preferably an npn-type bipolar transistor (BJT). In the case shown, the transistor Q2 operates at a collector current (Ic) at which the cutoff frequency is similar to that of the transistor Q1 of the oscillator 35, in particular is still higher than 13 GHz with Ic=60 mA and a power gain at 500 MHz greater than 20 dB.

As an alternative, the power amplifier 40 can be provided by means of any RF power amplifier of a known type that can be amplitude modulated. However, a single-transistor embodiment is preferable for reasons of cost and low power consumption.

The transmission device 10 according to the invention may be provided with an impedance matching stage 51 between the collector of the transistor Q2 and the RF output (i.e., the impedance of the antenna 50), which may comprise an inductor L3 between said collector and the supply +Vcc, a capacitor C7 between the collector and the ground, and a capacitor C8 between the collector and the RF output (values of L3, C7 and C8 specifically suitable for a 50-ohm RF output impedance are shown in FIG. 7). A reactive stage may possibly also be provided to further attenuate harmonics and, in the example shown, is formed by an inductor L4 (connected to the collector of the transistor Q2 via the capacitor C8) and by two grounded capacitors C9 and C10 connected to the terminals of the inductor L4.

Clearly, the values and specifications of the components shown in FIGS. 7 and 9 exemplify the case of a carrier frequency in the band around 434 MHz. However, it is easy for a person skilled in the art to change the values, the transistors, the microchip and the specific SAW resonator of the circuit of FIG. 3 or 8 so as to have the carrier frequency in another band available for short-range devices, for example 315 MHz, 868 MHz, 915 MHz, 2.4 GHz or 4.8 GHz.

According to one aspect of the invention, an RC filter 41 is provided between the output of the signal MOD1 of the microcontroller 15 and the input of the power amplifier 40, which in the shown embodiment is the base of the transistor Q2. Since in the preferred embodiment the signal MOD1 for driving the amplifier 40 is a voltage signal, the base of the transistor Q2 is provided with a base resistor R6 in order to be able to supply a current into said base with said signal.

In the detailed embodiment of FIG. 3, the RC filter 41 is interposed between the output MOD1 and said base resistor R6 and comprises a resistor R5 between the output MOD1 and a terminal of the base resistor R6 and, on said terminal, a capacitor C12 connected to the ground. The peak level of the PPM pulse generated at the output of the amplifier 40 is essentially determined by the series of the resistors R5 and R6.

The RC filter 41 formed by R5 and C12 is essentially a low-pass filter which, by virtue of the relative temporal arrangement of the signals MOD1 and MOD2 explained below, allows to provide at the output of the amplifier 40 a PPM pulse that has a quasi-Gaussian shape over time, i.e., an approximation of a Gaussian curve which, in terms of frequency, has no spurious harmonics with significant power levels, i.e., greater than −36 dBm (for frequencies below 1 GHz) or −30 dBm (for frequencies above 1 GHz) in a band comprised between 25 MHz and 6 GHz.

According to the invention, for each PPM pulse 200 to be generated in output to the generation means 33, the microcontroller 15 drives the oscillator 35 and the power amplifier 40 as follows:
it keeps the oscillator 35 and the power amplifier 40 off (step 301), i.e., it keeps both the signal MOD1 for driving the power amplifier 40 and the signal MOD2 for driving the oscillator 35 at the low value (i.e. zero), so as to minimize power consumption in the times between one PPM pulse and the next, as well as between one message and the next;
when there is a PPM pulse to be transmitted (step 302), microcontroller 15 activates the oscillator 35 only for a period T_OSC (also termed “oscillation time interval” here) that is equal to the sum T1+T2+T3 (step 303), i.e. it brings the signal MOD2 to the high value and keeps it high throughout the interval T_OSC and then returns it to zero. At the input of the oscillator 35, the current signal rises with a time constant defined by the RC stage 31 or 31′, for example by R1·C4 in the case of FIG. 3 or R1′·C3′ in the case of FIG. 8;
after a first time period T2 from the beginning of said interval T_OSC (step 304), i.e., starting from the rising edge of the rectangular pulse of the signal MOD2, the microcontroller 15 also activates the power amplifier 40 but only for a second time period T1 such that the sum of the first and second time periods (T2+T1) is less than the oscillation time interval T_OSC (step 305). In other words, after the first time period T2, the microcontroller 15 brings the signal MOD1 to the high value and keeps it high exclusively for said second time period T1 and then returns it to zero. The time constant defined by the RC stage 31 at the input of the oscillator 35 (R1·C4 or R1′·C3′) may be such as to reach an essentially overdrive condition of the power amplifier 40 halfway along the second time period T1;
after the second time period T1 has elapsed (step 306), the microcontroller 15 deactivates only the power amplifier 40 (step 307), keeping only the oscillator 35 completely active (i.e., keeping only the signal MOD2 at the high level) until the oscillation time interval T_OSC expires, i.e., for a third time period T3 (other than zero) after which (step 308) the oscillator 35 is deactivated by the microcontroller 15, bringing the signal MOD2 to the low value (step 309), i.e. to zero.

The values T1, T2, T3 are advantageously chosen as follows.

The first time period T2 or “pre-pulse time” is preferably the shortest one required to stabilize the oscillations in output from the oscillator 35 following its power-on initiated by the driving signal MOD2, but it can also be a shorter time.

Preferably, T2 has a value comprised between 0.5 and 5 microseconds. The frequency of the oscillations is preferably an RF frequency of one of the so-called free bands, for example, a frequency of the ISM or SRD band. In the embodiment shown, such a frequency is comprised between 433.05 MHz and 434.79 MHz, for example 434.35 MHz.

The second time period T1 or “pulse time” or “activation time” of the amplifier 40 substantially corresponds to the duration of the single PPM pulse to be transmitted in radiofrequency (i.e. the pulse width at −3 dB) and can be comprised between 1 and 5 microseconds. A duration of T1 comprised between 1.8 and 2.5 microseconds is preferable in order to reduce the risk of not complying with the OBW tests of international standards such as those mentioned herein initially.

The third time period T3 or “post-pulse time” is chosen so as to amplify decreasingly over time the signal in output from the oscillator 35 and is preferably comprised between 0.5 and 5 microseconds. In particular, the RC filter 41 allows to slow the falling edge of the driving signal MOD1 at the input of the amplifier 40 (which would otherwise be stepped) and therefore to apply a gradually attenuated amplification of the RF signal generated by the oscillator 35, which is still kept active throughout the third time period T3.

While the time constant R1·C4 or R1′·C3′ of the RC stage 31 or 31′ at the input of the oscillator 35 can be chosen in order to substantially determine the decay time of the falling edge 204 of the PPM pulse, the time constant of the RC filter 41 at the input of the amplifier 40 (R101·C101 or R5·C12) is chosen not only to determine the rising time of the rising edge 202 of the PPM pulse but also to eliminate or in any case attenuate spurious emissions, which in the case of the invention would essentially be harmonics.

It was in fact surprisingly found that such a gradually decreasing amplification, by means of the RC filter 41, of the signal in output from the still active oscillator 35 and obtained during the third time period T3, allows to smooth the falling edge of the PPM pulse 200 at the output of the amplifier 40, resulting in a knee 203 that is essentially free of angular points on the falling edge. The rising edge 202 of the PPM pulse also is substantially free of angular points or slope discontinuities.

Altogether, the PPM pulse 200 at the output of the generation means 33 thus turns out to be quasi-Gaussian or pseudo-Gaussian, i.e. suitable to avoid the generation of out-of-band frequency peaks beyond the threshold power levels usually provided in the standards (−30 dBm or −36 dBm), i.e. to avoid spurious emissions and to meet, in this respect, the international standards mentioned herein initially.

If the third time period T3 were instead zero as described in the background art represented by patent U.S. Pat. No. 10,284,120 mentioned above, i.e., if both signals MOD1 and MOD2 were brought to the low level at the same instant and without any RC filter 41, the region 203 would have a concavity change, i.e., the power level of the spurious emissions would increase.

The third time period T3 between the falling edge of the signal MOD1 for driving the amplifier 40 and the falling edge of the signal MOD2 for driving the oscillator 35 can have a value comprised between 0.5 and 5 microseconds, i.e., substantially equal to or lower than the time constant of the above-mentioned RC filter 41 placed between the output MOD1 of the microcontroller 15 and the input of the power amplifier 40.

With reference to the RC stage 31 at the input of the oscillator 35 and on which the driving signal MOD2 is applied, the resistor R1 (or R0 in FIG. 2) preferably has a resistance comprised between 1 kΩ and 100 kΩ, while the capacitor C4 (or C0 in FIG. 2) preferably has a capacitance comprised between 22 pF and 2200 pF, so as to define a time constant of the RC stage 31 comprised between 0.5 and 2 microseconds. Similar resistance and capacitance values are provided for the RC stage 31′ of the oscillator of FIG. 8.

In the RC filter 41, the resistor R5 (or R101 in FIG. 3) can have a resistance comprised between 1 kΩ and 100 kΩ, while the capacitor C12 (or C101 in FIG. 2) preferably has a capacitance comprised between 100 pF and 10 nF, so as to define a time constant of the RC filter 41 comprised between 1 and 10 microseconds.

In practice it has been found that the invention achieves the intended aim and objects.

The invention thus conceived is susceptible of numerous modifications and variations, all of which are within the scope of the inventive concept; all the details may furthermore be replaced with other technically equivalent elements.

In practice, the materials used, as well as the contingent shapes and dimensions, may be any according to the requirements and the state of the art.

The disclosures in Italian Patent Application no. 102022000009020, from which this application claims priority, are incorporated herein by reference.

Where technical features mentioned in any claim are followed by reference signs, those reference signs have been included for the sole purpose of increasing the intelligibility of the claims and accordingly such reference signs do not have any limiting effect on the interpretation of each element identified by way of example by such reference signs.

1-12. (canceled)

13. A transmission device for the radio transmission of local measurements of physical values comprises a microcontroller and a pulse generator connected to the microcontroller, the microcontroller being adapted to receive at least one detection signal that is representative of at least one measurement value and to control the pulse generator so that it generates at least one PPM signal which comprises information that corresponds to the at least one measurement value,
the transmission device further comprising, or being connectable to, an antenna for the radio transmission of the PPM signal,
the pulse generator comprising an oscillator and a power amplifier with an input connected to the oscillator to amplify RF pulses in output from the oscillator and emit the PPM signal on the basis of a selective activation of the oscillator and of the power amplifier by respective driving signals with rectangular pulses generated by the microcontroller,
wherein the microcontroller is adapted, for each PPM pulse of the PPM signal to be generated, to activate and deactivate the oscillator and the power amplifier so that the oscillator is activated prior to the activation of the power amplifier and is deactivated after the deactivation of the power amplifier, and
wherein the transmission device further comprises a low-pass filter between the microcontroller and the power amplifier, the low-pass filter being adapted to slow the deactivation of the amplifier while the oscillator is kept active by the respective driving signal.

14. The transmission device according to claim 13, wherein the microcontroller is adapted, for each PPM pulse of the PPM signal to be generated, to activate and deactivate the oscillator and the power amplifier according to the following sequence:
activating the oscillator only for an oscillation time interval;
after a first time period from the beginning of the oscillation time interval, activating the power amplifier only for a second period of time such that the sum of the first and second time periods is smaller than the oscillation time interval, and deactivating the amplifier at the end of the second time period; and
for a third time period after the second time period, leaving only the oscillator active until the oscillation time interval expires, then deactivating the oscillator,
wherein the low-pass filter is adapted to slow the deactivation of the amplifier during the third time period.

15. The transmission device according to claim 14, wherein the microcontroller is adapted to generate the driving signals on corresponding outputs thereof which are connected respectively to the oscillator and to the power amplifier,
the driving signals consisting of a first signal for driving the power amplifier and of a second signal for driving the oscillator,
the first driving signal being supplied by a first output of the microcontroller which is connected to the power amplifier,
the second driving signal being supplied by a second output of the microcontroller which is connected to the oscillator,
wherein each rectangular pulse of the first driving signal has a duration equal to the second time period and each rectangular pulse of the second driving signal has a duration equal to the oscillation time interval.

16. The transmission device according to claim 15, wherein the first driving signal is supplied by a first output of the microcontroller which is connected to the power amplifier,
the power amplifier comprises an input transistor, and
the first output of the microcontroller is connected to an activation terminal of the transistor across the low-pass filter.

17. The transmission device according to claim 16, wherein the second driving signal is supplied by a second output of the microcontroller which is connected to the oscillator,
the oscillator comprises an input RC stage, and
the second output of the microcontroller is connected to the oscillator so as to apply the second driving signal to the RC stage.

18. The transmission device according to claim 14, wherein the second time period is from 1 to 5 microseconds.

19. The device according to claim 18, wherein the first time period or the third time period is from 0.5 to 5 microseconds.

20. The device according to claim 13, wherein the RC filter has a time constant of from 1 to 10 microseconds.

21. A method for the radio transmission of local measurements of physical values, performed by a transmission device comprising a microcontroller, a pulse generator connected to the microcontroller, and an antenna, the pulse generator comprising an oscillator and a power amplifier with an input connected to the oscillator to amplify RF pulses in output from the oscillator, the method comprising the steps of:
receiving at least one detection signal in the microcontroller that is representative of at least one locally detected measurement value; and
PPM modulating at least one information item contained in the at least one detection signal and generating a first rectangular pulse and a second rectangular pulse for each PPM pulse of the PPM signal to be generated with the pulse generator,
the first rectangular pulse lasting for a second time period and being supplied to the power amplifier to keep it active only for the second time period,
the second rectangular pulse having a duration that is greater than the second time period and being supplied to the oscillator to keep it active for the duration,
wherein, for each PPM pulse, the oscillator and the power amplifier are activated and deactivated so that the oscillator is activated prior to the activation of the power amplifier and is deactivated after the deactivation of the power amplifier, and
wherein the first rectangular pulse is supplied to the power amplifier after subjecting it to a low-pass filter to slow the deactivation of the power amplifier.

22. The method according to claim 21, wherein, for each PPM pulse, the oscillator and the power amplifier are activated and deactivated by a sequence comprising the steps of:
applying the second rectangular pulse to the oscillator to keep the oscillator active only for the duration;
after a first time period from the beginning of the second rectangular pulse, applying the first rectangular pulse to the power amplifier to keep it active only for the second time period such that the sum of the first time period and the second time period is less than the duration; and
for a third time period T3 after the second time period, keeping only the oscillator active until the duration expires, and subsequently deactivating the oscillator,
wherein the deactivation of the power amplifier is slowed during the third time period.

23. The method according to claim 22, wherein the second time period is from 1 to 5 microseconds.

24. The method according to claim 22, wherein the first time period or the third time period is from 0.5 to 5 microseconds.
